(19) United States
(12) Patent Application Publication
(10) Pub. No.: US 2009/0213565 A1
(43) Pub. Date: Aug. 27, 2009

(54) EMC SHIELDING FOR PRINTED CIRCUITS USING FLEXIBLE PRINTED CIRCUIT MATERIALS

(75) Inventors: Roger A. Booth, Jr., Wappingers Falls, NY (US); John M. Dangler, Rochester, MN (US); Matthew S. Doyle, Rochester, MN (US)

Correspondence Address: CANTOR COLBURN LLP - IBM ROCHESTER DIVISION, 20 Church Street, 22nd Floor, Hartford, CT, 06103, US

(73) Assignee: INTERNATIONAL BUSINESS MACHINES CORPORATION, Armonk, NY (US)

(21) Appl. No.: 12/038,356

(22) Filed: Feb. 27, 2008

(51) Int. Cl. H05K 9/00; H01R 43/00

(52) U.S. Cl. 361/818; 29/825

(57) ABSTRACT

Exemplary embodiments of the present invention relate to a method for making multilayer flexible printed circuit carrier. The method comprises producing a first flexible conductor layer having a first width, producing a second flexible conductor layer having a second width larger than the first width, and separating a first side of the first flexible conductor and a first side of the second flexible conductors with a first insulator. The method also comprises placing a second insulator over at least a portion of a second surface of the first flexible conductor, and wrapping a portion of the second flexible conductor over the at least a portion of the second surface of the first flexible conductor.

### BACKGROUND OF THE INVENTION

1. Field of the Invention

This invention relates to electromagnetic compatibility, and particularly to the shielding of electrical components from electromagnetic interference.

2. Description of Background

Electromagnetic compatibility (EMC) refers to operations or mechanisms that are instituted to avoid the effects of electromagnetic interference (EMI) from the unintentional generation, reception, and propagation of electromagnetic energy. In particular, EMC addresses the effects of EMI emission issues and the appropriate countermeasures that may be implemented in order to reduce the generation of EMI.

EMC shielding of electronic components (e.g., high speed cards and flexible electronic circuits (flex circuits)) is very important. As such, the implementation of EMC shielding can be extremely challenging within mechanically flexible and cost-sensitive environments. Existing EMC shielding solutions typically involve the structural reconfiguration of a component to comprise additional internal physical copper layers, external woven impregnated fabric or ink enclosures, or an external EMC containment (e.g., such as sheet metal). The short comings of these solutions can include resultant unsealed edges within physical copper solutions, in addition the added cost of parts and restrictions in regard to the physical space requirements for such solutions. Conventionally, stitching vias are implemented to reduce EMC emission from the edge/sides of high speed cards and flex circuits. However, in some cases, the stitching vias do not provide sufficient attenuation of radiated noise.

### SUMMARY OF THE INVENTION

The shortcomings of the prior art are overcome and additional advantages are provided through the provision of a method for making multilayer flexible printed circuit carrier. The method comprising producing a first flexible conductor layer having a first width, producing a second flexible conductor layer having a second width larger than the first width, and separating a first side of the first flexible conductor and a first side of the second flexible conductors with a first insulator. The method also comprises placing a second insulator over at least a portion of a second surface of the first flexible conductor, and wrapping a portion of the second flexible conductor over the at least a portion of the second surface of the first flexible conductor.

Further provided is a multilayer flexible printed circuit carrier produced by producing a first flexible conductor layer having a first width, producing a second flexible conductor layer having a second width larger than the first width, and separating a first side of the first flexible conductor and a first side of the second flexible conductors with a first insulator. Also performed is placing a second insulator over at least a portion of a second surface of the first flexible conductor and wrapping a portion of the second flexible conductor over the at least a portion of the second surface of the first flexible conductor.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### BRIEF DESCRIPTION OF THE DRAWINGS

The subject matter that is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 illustrates one example of the structural configuration for a prior art hard card or flex circuit board comprising frame ground layers and frame ground stitching vias.

FIG. 2 illustrates one example wherein the frame ground layer of a circuit board is offset from the remaining layers of a stack-up in accordance with the exemplary embodiments of the present invention.

FIG. 3 illustrates one example wherein the frame ground layer offset layers are wrapped around the edges of the circuit board in accordance with the exemplary embodiments of the present invention.

FIGS. 4A and 4B illustrate examples wherein the flexible layer is completely wrapped around the circuit board in accordance with the exemplary embodiments of the present invention.

The detailed description explains the preferred embodiments of the invention, together with advantages and features, by way of example with reference to the drawings.

### DETAILED DESCRIPTION OF THE INVENTION

One or more exemplary embodiments of the invention are described below in detail. The disclosed embodiments are intended to be illustrative only since numerous modifications and variations therein will be apparent to those of ordinary skill in the art. In reference to the drawings, like numbers will indicate like parts continuously throughout the views.

The exemplary embodiments of the present invention provide a mechanical solution for the increased effectiveness of EMC seals. The exemplary embodiments of the present invention further provide a structure that uses the integral cross-sectional layer of a high speed card or flex circuit as an EMC shield for any structural design that contains high speed signals. In configuration, a copper layer comprised within a circuit board is offset with respect to a remaining component stack-up and thereafter is laminated as an assembly and used as an EMC shield layer within the structure. Within exemplary embodiments, the offset layer can be folded over a circuit board in order to provide a 360° EMC shield for the circuit board structure.

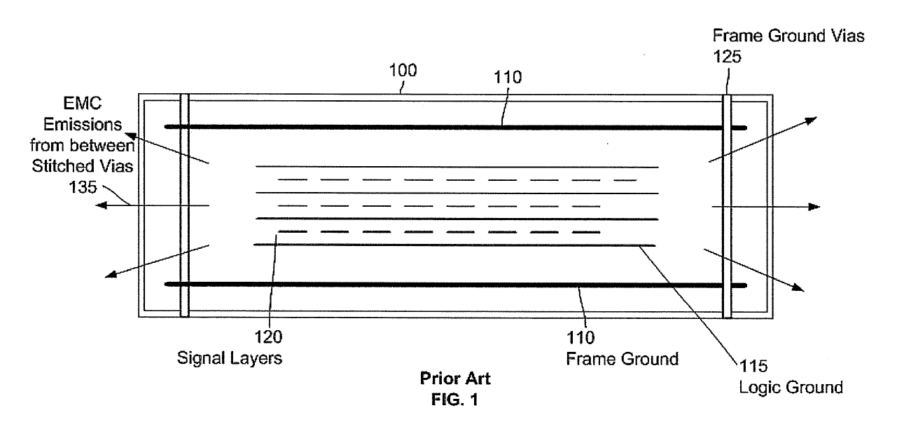

FIG. 1 shows a standard prior art configuration for a hard card or flex circuit board 100. The frame ground layers 110 and the frame ground stitching vias 125 that typically are placed around the edge of the component part. Also comprised within the circuit board 100 are a plurality of signal trace layers 120 and logic ground trace layers 115. As shown, EMC emissions 135 can radiate from the edges of the circuit board 100 between the frame ground stitching vias 125.

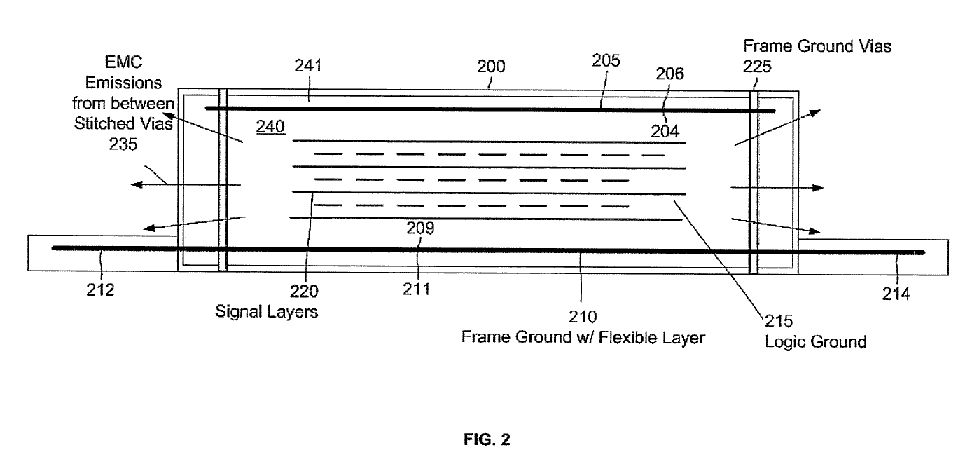

FIG. 2 shows a circuit board 200 that is configured with an extended flexible EMC shield layer in accordance with the exemplary embodiments of the present invention. As shown, the circuit board 200 comprises a first and second flexible conductor layer/frame ground trace 205, 210, wherein the conductive layer comprises any flexible and conductive material (e.g., such as copper). Also comprised between the frame ground layers 205, 210 are a plurality of signal layers 220 and logic ground layers 215, the signal layers 220 and logic ground layers 215 also being comprised of flexible conductive materials. The first 205 and second 210 flexible conductor layers have a dielectric insulator material 240 situated between the respective first surfaces 204, 209 of the conductive layers 205, 210. While the first 205 flexible conductor layer has a further dielectric insulating material 241 in contact with its second surface 206. As shown, EMC emissions 235 can radiate from between the edges of the plate-through-the-hole frame ground stitching vias 225.

The first flexible conductive layer 205 has a first 204 and second 206 surface area. The second flexible conductive layer 210 also has a first 209 and second 211 surface area. The second flexible conductive layer 210 is continuously offset from the standard design stack-up layers of 205, 215, and 220 on either side by extended flexible layers 212 and 214. Within the exemplary embodiments the flexible layers can be laminated with conventional flexible materials (e.g., polyimide).

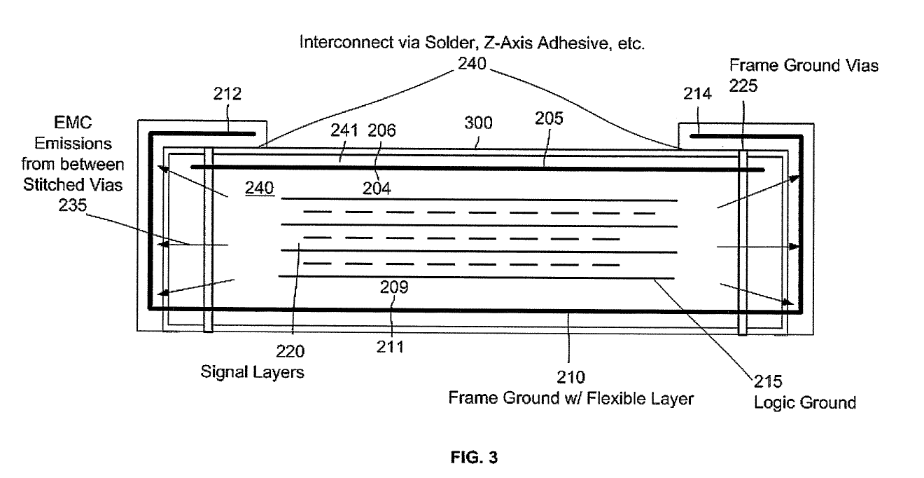

FIG. 3 shows a circuit board 300 wherein the flexible offset layers 212, 214 are wrapped around the edges of the circuit board 300 in accordance with exemplary embodiments of the present invention. The flexible offset layers 212, 214 can be structurally configured as needed to provide access for solder, Z axis adhesive or other interconnection technology to complete the enclosure 240 of the flexible offset layers 212, 214 to the portion of the circuit board 300 comprising the second surface 206 of the first flexible conductor layer 205.

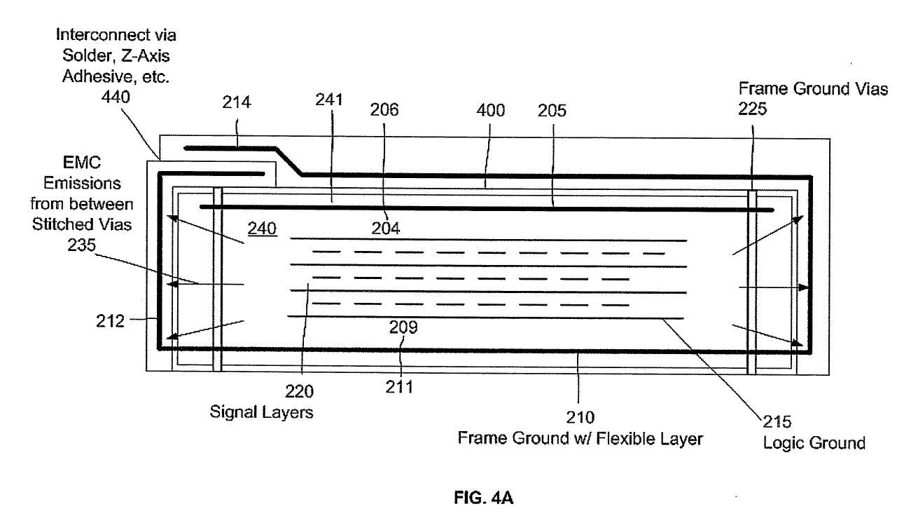

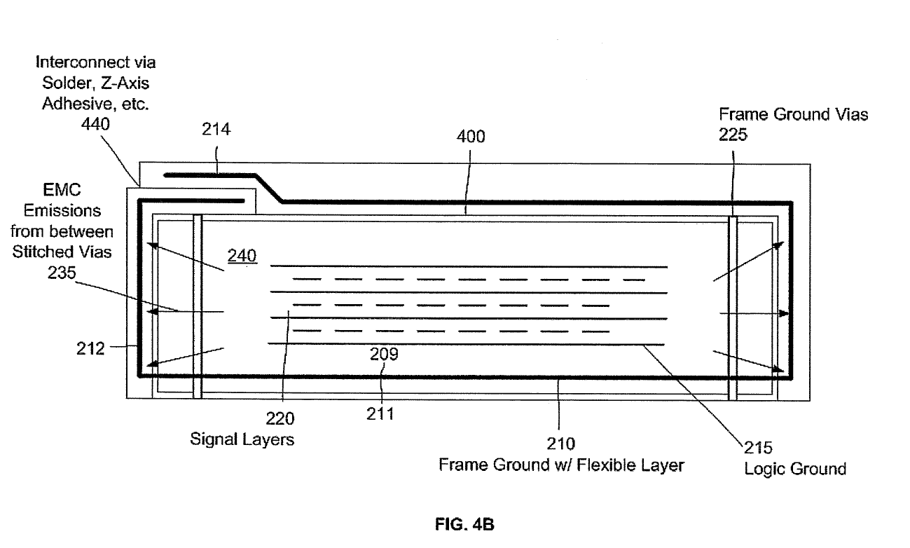

FIGS. 4A and 4B show an exemplary embodiment wherein by lengthening the flexible offset layer 214, the flexible offset layers 212, 214 can be wrapped around the circuit board 400 and attached to each other at a contact point 440. The ends of the flexible offset layers 212, 214 can be terminated by the use of additional means such as the crimping, overlapping, or folding-over of the ends of the flexible offset layers 212, 214 with each other. This configuration in particular results in the reduction of the number of exposed seams within a circuit board 400. And as shown in FIG. 4B, the present configuration further makes optional the need for implementing the first flexible conductor layer 205 at the top of the circuit board 400 (as shown in FIG. 4B), thus resulting in the reduction of the stack-up layer count by one layer.

Within yet further exemplary embodiments the flexible offset layers 212, 214 can comprise a copper plane characterized by etching or punching. These flexible offset layers can be characterized to an EMC compatible perforation pattern. The flexible offset layers 212, 214 can then be wrapped around circuit board 200 components after assembly, thus creating an integrated EMC enclosure for the components

As one example, one or more aspects of the present invention can be included in an article of manufacture (e.g., one or more computer program products) having, for instance, computer usable media. The article of manufacture can be included as a part of a computer system or sold separately.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

What is claimed is:

1. A method for making multilayer flexible printed circuit carrier comprising:
producing a first flexible conductor layer having a first width;
producing a second flexible conductor layer having a second width larger than the first width;
separating a first side of the first flexible conductor and a first side of the second flexible conductors with a first insulator;
placing a second insulator over at least a portion of a second surface of the first flexible conductor; and
wrapping a portion of the second flexible conductor over at least a portion of the second surface of the first flexible conductor.

2. A multilayer flexible printed circuit carrier produced by:
producing a first flexible conductor layer having a first width;
producing a second flexible conductor layer having a second width larger than the first width;
separating a first side of the first flexible conductor and a first side of the second flexible conductors with a first insulator;
placing a second insulator over at least a portion of a second surface of the first flexible conductor; and
wrapping a portion of the second flexible conductor over at least a portion of the second surface of the first flexible conductor.
